(19) United States
(12) Patent Application Publication
(10) Pub. No.: US 2003/0227952 A1
(43) Pub. Date: Dec. 11, 2003

(54) VCSEL device with single-mode output

(76) Inventors: Su-Wei Chiu, Hsinchu Hsien (TW); Hung-Pin Yang, Taipei Hsien (TW); Chia-Pin Sung, Hsinchu (TW); Jim-Yong Chi, Taichung (TW)

Correspondence Address: BIRCH STEWART KOLASCH & BIRCH, PO BOX 747, FALLS CHURCH, VA, 22040-0747, US

(21) Appl. No.: 10/300,886

(22) Filed: Nov. 21, 2002

(30) Foreign Application Priority Data
Jun. 7, 2002 (TW) 091112297

(51) Int. Cl. H01S 5/00; H01S 3/08

(52) U.S. Cl. 372/45; 372/46; 372/96

(57) ABSTRACT

This specification discloses a VCSEL (Vertical Cavity Surface-Emitting Laser) device with single-mode output. This device is given by coating a layer of antireflection-coating (AR-coating) film on a normal VCSEL device with multiple transverse mode output and forming a light-emitting window on the AR-coating film. Since the AR-coating film can lower the reflectivity of the VCSEL device with multiple transverse mode output and the Bragg reflector at the bottom of the AR-coating film, it is easier to form single-mode laser light when the current flows through areas not covered by the AR-coating film, outputting a single-mode laser beam. Through the power-current character curve and the spectrum properties, one can find an optimal electrical current value for controlling single-mode light output.

### BACKGROUND OF THE INVENTION

1. Field of Invention

The invention relates to a VCSEL (Vertical Cavity Surface Emitting Laser) and, in particular, to a VCSEL with single-mode output.

2. Related Art

The vertical cavity surface emitting laser (hereinafter as VCSEL) is a surface-emitting type semiconductor laser. It is mainly used as a optical transmission devices in optical communications transceivers and optical information pickup heads. It has the advantages of a low threshold current, a high operation speed (1-10 Gbps) and a high fiber coupling rate.

In practice, VCSEL can emit multiple transverse mode or single mode according to their transmission spectra. The VCSELs with single-mode output can have a longer transmission distance. The maximum distance is two kilometers. The transmission distance of those with multiple transverse mode is shorter because the signal attenuation is serious when being transmitted over multiple transverse mode fibers. The current technology can achieve a distance of 300 to 500 meters. Therefore, the multiple transverse mode VCSEL devices are mostly used in short-distance transmissions in Ethernets.

The VCSEL structure is mainly comprised of an upper and a lower multiple-layer distributed Bragg reflectors (DBR), an active region, a substrate, and P-type and N-type metals. The manufacturing methods for the VCSELs include ion implantation and oxide confinement. The devices shown in FIGS. 1A, 1B and 1C are the multiple transverse mode VCSELs made by the ion implantation, airpost etch, and selective oxidation technology, respectively. As shown in FIG. 1A, the VCSEL consists of, from the bottom to the top, an N-type metal 11, a substrate 10, an N-type DBR 20, an active region 30, a P-type DBR 40, a proton-implanted region 32, and a P-type metal 41. When a current flows through the active region 30, the active region 30 starts to emit laser beam when the current is larger than an threshold current density. The laser is emitted out of a light-emitting window 52, 52a, 52b as a laser beam 51, 51a, 51b. The VCSELs made using the oxide confinement technology can be obtained by replacing the proton-implanted area 32 by an oxide layer 34b. Of course, there exists other different VCSEL manufacturing methods.

With further reference to FIGS. 1A, 1B and 1C, if one wants to make a single-mode VCSEL device the width W′ of the proton-implanted area 32 in the P-type DBR 40 has to be narrowed. At the same time, the width W1 of the light-emitting window 52 in the P-type metal 41 formed on top of the device has to be narrowed, too. However, restricting these two diameters are not easy to control and, therefore, the yield is lower.

In addition, the single-mode VCSEL made using the ion implantation technology has a larger series resistance. Thus, the speed is lower and the maximum output power is about 1 m W. This is mainly because the light-emitting area can be easily affected by the proton implantation defects, therefore lowering the laser power and its reliability. The single-mode VCSEL device made using the oxide-confined technology also suffers from the difficulty that the current-confined region in the oxide layer has a small diameter, which makes the oxidation depth difficult to control. This type of VCSELs have the drawbacks such as lower yields, higher resistance, and lower operation speeds.

The above-mentioned problems have to be solved in order to obtain single-mode VCSEL devices with higher yields. Therefore, how to develop single-mode VCSEL devices based upon available multiple transverse mode VCSEL manufacturing technologies is the main topic for VCSEL devices.

### SUMMARY OF THE INVENTION

In view of the foregoing, the invention provides a VCSEL device with single-mode output. An antireflection-coating (AR-coating) film is formed on the original top light-emitting window of the VCSEL. A single-mode light-emitting window with a diameter smaller than or equal to 5 μm is formed at the center of the thin film. In practice, this processing technique is easier and can be to precisely controlled, and therefore has a higher yield such that the manufacturing cost can be lowered.

To achieve the objective mentioned above, the disclosed single-mode VCSEL contains: a multiple transverse mode VCSEL with a top light-emitting area and a layer of AR-coating film. The AR-coating film is formed at the top light-emitting area of the multiple transverse mode VCSEL device. A single-mode light-emitting window is further opened on the AR-coating film for restricting the output of the multiple transverse mode VCSEL into a single-node laser beam.

The above-mentioned VCSEL with multiple transverse mode output can be any type of multiple transverse mode VCSEL, such as the ion implanted VCSEL, or the oxide-confined VCSEL, or the oxide-confined VCSEL with the intracavity contacts.

The AR-coating film 250 is made of materials with a very high refractive index, such as Ge (with a refractive index of 5.2+0.65j), or a single-layer or multiple-layer AR's made of other dielectrics.

In addition, the invention further provides a method for forming the VCSEL with single-mode output. The method integrates the manufacturing method of VCSELs with multiple transverse mode output to make the disclosed single-mode VCSEL. The method comprises the steps of: making a VCSEL using the procedure for a typical VCSEL with multiple transverse mode output; and forming an AR-coating film on the light-emitting window of the VCSEL, which has a single-mode light-emitting window formed at the center.

According to the power-current characteristic curve of the VCSEL device with single-mode output, one is able to find an optimun electrical current value for single-mode light output. Once the optimum electrical current is applied to the disclosed VCSEL device, we can obtain a single-mode laser beam output.

### BRIEF DESCRIPTION OF THE DRAWINGS

The invention will become more fully understood from the detailed description given hereinbelow illustration only, and thus are not limitative of the present invention, and wherein:

FIGS. 1A through 1C are schematic views of the conventional multiple transverse mode VCSELs;

FIG. 2 is a top view of the disclosed single-mode VCSEL;

FIG. 3 shows a first embodiment of the disclosed single-mode VCSEL;

FIG. 4 shows a second embodiment of the disclosed single-mode VCSEL;

FIG. 5 shows a third embodiment of the disclosed single-mode VCSEL;

FIG. 6 shows the single-mode output spectrum of the invention using Ge as the AR-coating film with a light-emitting window of 5 μm in diameter;

FIG. 7 shows the power-current characteristics of the invention using Ge as the AR-coating film with a light-emitting window of 5 μm in diameter;

FIG. 8 shows the relative spectra of the invention at different current levels using Ge as the AR-coating film with a light-emitting window of 5 μm in diameter;

FIG. 9 shows the relative spectra of the conventional VCSEL with a light-emitting aperture of 20 μm without an AR-coating film; and

FIG. 10 shows the decrease in the reflectivity with the increase in the refractive index of the AR-coating film on top of the disclosed DBR.

### DETAILED DESCRIPTION OF THE INVENTION

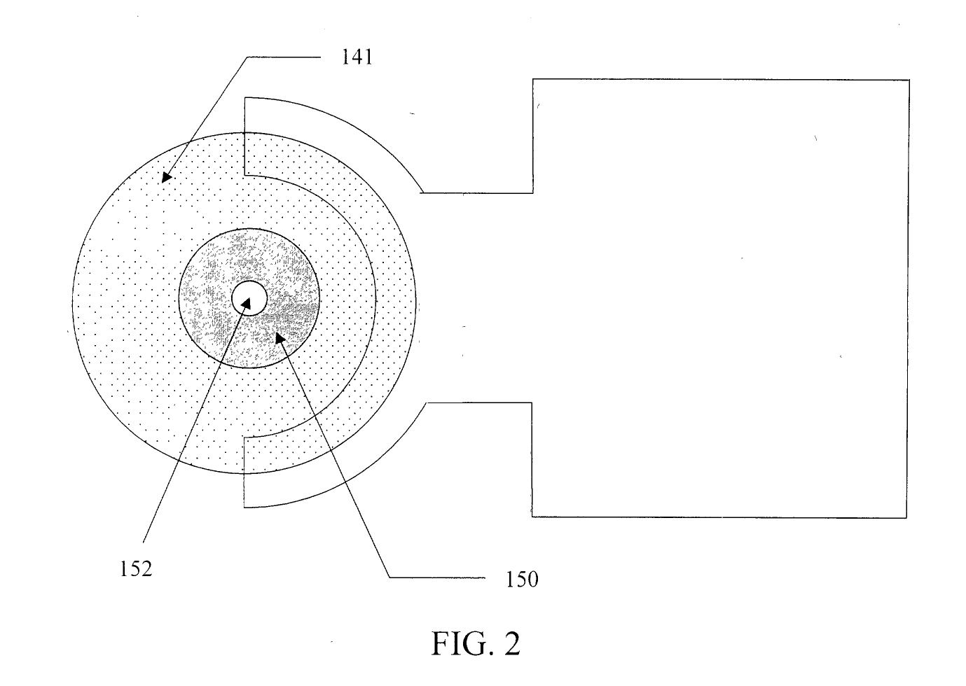

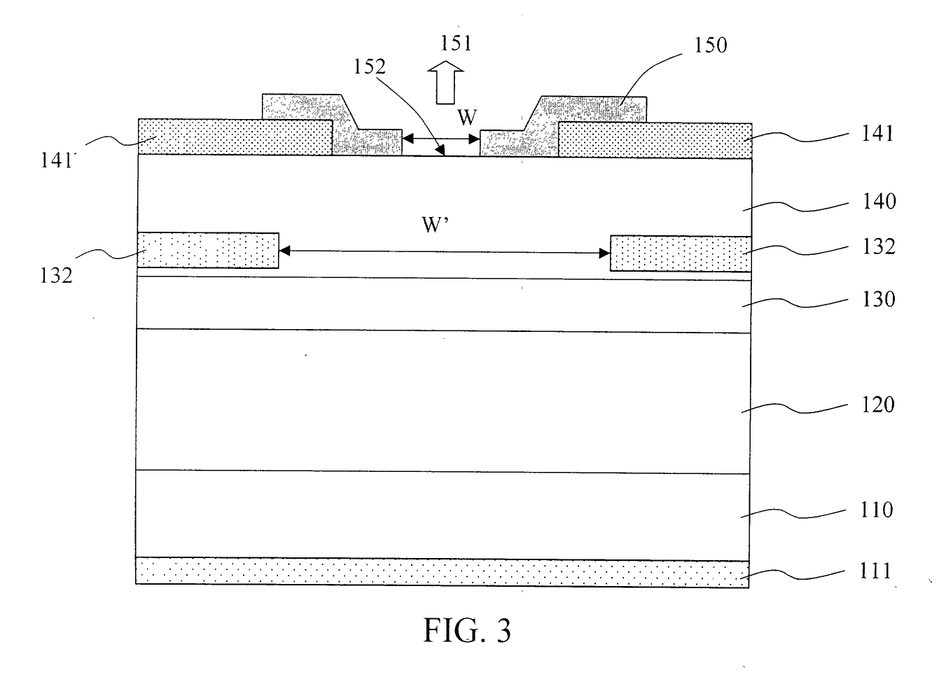

The operating principles of the disclosed VCSEL device with single-mode output are described as follows. Take a normal multiple transverse mode VCSEL and form an AR-coating film on the original top light-emitting window (with a diameter greater than 5 μm). The top light-emitting window is located at the center of the annular P-type metal 141. The thin film is formed with a single-mode light-emitting window 152 with a diameter smaller than 5 μm, as shown in FIGS. 2 and 3. Due to the existence of the AR-coating film 150, the combined reflectivity of the underlying AR-coating film and the P-type DBR covered thereby becomes smaller. This makes the active region under the covered AR-coating film difficult to reach its threshold condition for emitting laser. This in turn makes the current flow through the region not covered by the AR-coating film (with a diameter smaller than 5 μm) to emit a single-mode laser beam. Since the aperture of the original P-type metal (with a diameter W′) is larger, the series resistance of the VCSEL device is smaller.

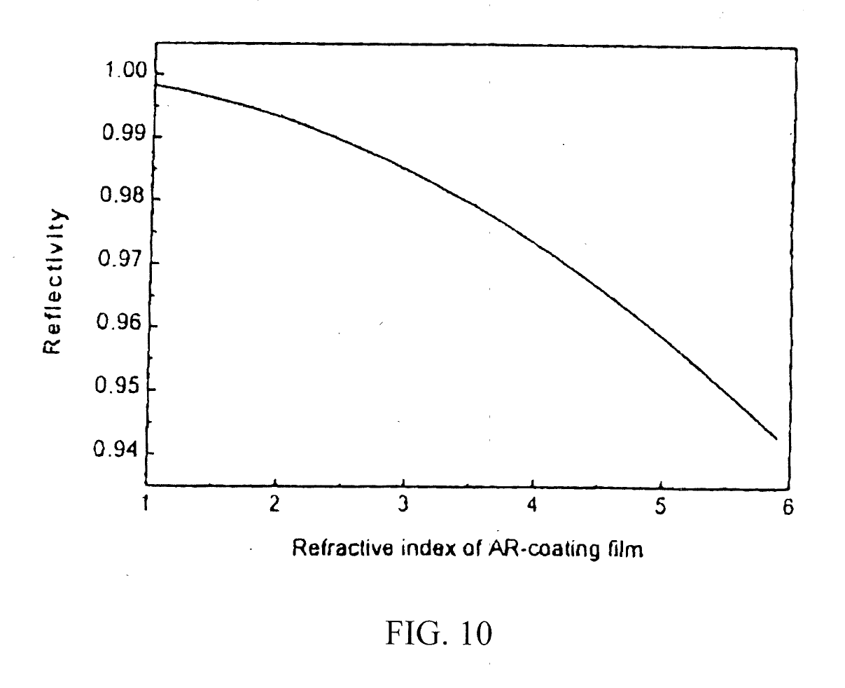

Please refer to FIG. 10 for the effect of the lowered reflectivity due to the existence of the AR-coating film.

The formation of the AR-coating film can be done by direct deposition or by evaporation after the multiple transverse mode VCSEL is finished. The single-mode light-emitting window is subsequently formed by a liftoff a or etching process.

Please refer to FIGS. 3 through 5 for explicit embodiments, which illustrate the AR-covered ion-implanted VCSEL, the oxide-confined VCSEL and the intracavity-contacted oxide-confined VCSEL with intracavity contacts.

First, please refer to the embodiment shown in FIG. 3. The device consists of, from bottom to top, an N-type metal 111, a substrate 110, an N-type DBR 120, an active region 130, a P-type DBR 140, a proton-implanted area 132, a P-type metal 141, and an AR-coating film 150. The AR-coating film 150 is the essence of the invention.

The bottom laser mirror of the VCSEL is an N-type DBR 120. The top laser mirror is a P-type DBR 140. At the center of the AR-coating film 150 is formed with a light-emitting window 152 with a diameter W smaller than 5 μm. The light beam 151 (single-mode laser) is output through the top light-emitting window 152. Besides, the N-type and P-type DBR's 120, 140 are made of tens of pairs of materials with high-low refractive indices. The thickness is ¼ of the wavelength λ of the emitted light, so that the total reflectivity reaches above 98%. The active region 130 is comprised of a quantum well and confiment layer. The active region 130 has a thickness of the emitted light wavelength λ. Its thickness can also be designed to be the multiples of λ/2. The proton-implanted area 132 is formed by proton implantation, forming the damaged regions in the P-type DBR 140 and thus restricting the current flows to the undamaged region with a diameter W′ at the center. The damaged region 132 has a high impedance so that the current flows to the central light-emitting active area. The N-type metal 111 can be AuGe/Ni/Au and is evaporated at the bottom of the VCSEL device. The P-type metal 141 can be Ti/Pt/Au. The substrate 110 can be an N-type heavily doped GaAs or InP substrate.

The overall reflectivity of the area cover with AR-coating film 150 on top of the P-type DBR 140 can be lower. That is, it is more difficult for the active area covered by the AR-coating film to achieve the threshold condition for emitting laser beams. Therefore, the threshold current density of the area increases. On the other hand, the current flows through the central active region under the P-type DBR without AR-coating reach threshold current at lower current level and emit single-mode laser beam. Moreover, the AR-coating film 150 can be made of materials with high refractive indices, such as Ge (with a refractive index of 5.2+0.65j) or single-layer or multiple-layer AR's made of other dielectrics.

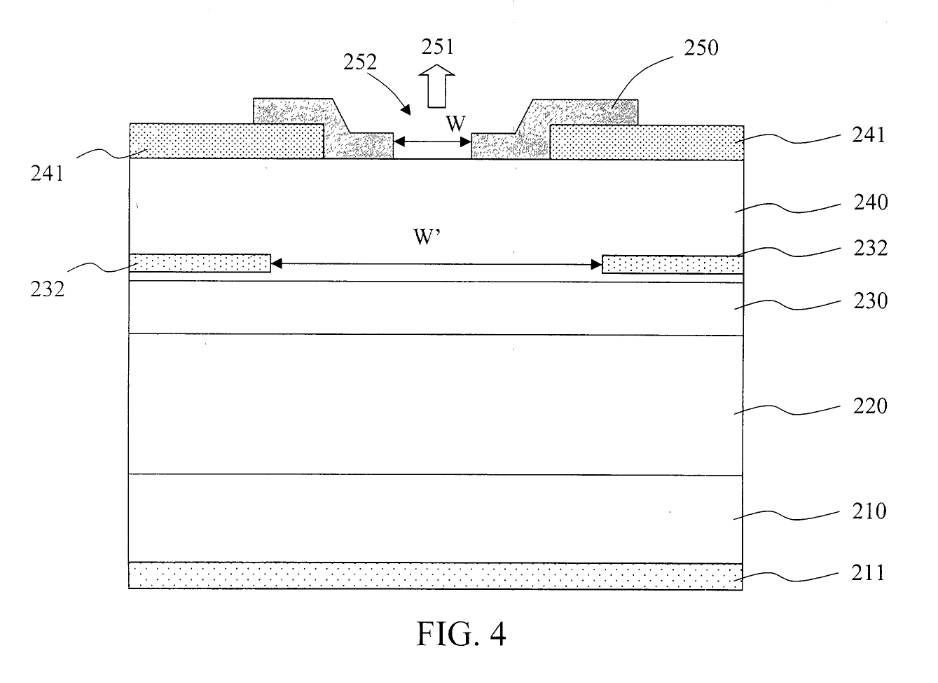

In the second embodiment demonstrated in FIG. 4, the invention consists of, from bottom to top, an N-type metal 211, a substrate 210, an N-type DBR 220, an active region 230, a P-type DBR 240, an oxide layer 232, a P-type metal 241, and an AR-coating film 250. The AR-coating film 250 is the essence of the invention.

The bottom laser mirror of the VCSEL device is an N-type DBR 220, and the top laser mirror is a P-type DBR 240. At the center of the AR-coating film 250, a light-emitting window 252 is formed with a diameter W smaller than 5 μm. The light beam 251 (single-mode laser) is output from the top light-emitting window 252. Besides, the N-type and P-type DBR's 220, 240 are made of tens of pairs of materials with high-low refractive indices. The thickness is ¼ of the wavelength λ of the emitted light, so that the total reflectivity reaches above 98%. The active region 230 is comprised of a quantum well and confinement layers. The active region 230 has a thickness of the emitted light wavelength λ. Its thickness can also be designed to be the multiples of λ/2. The oxide layer 232 is formed by selective oxidation, so as to restrict the current flows to the current un-oxidized region with a diameter W′. The oxidized region 232 has high impedance so that the current flows to the central light-emitting active region. The N-type metal 211 can be AuGe/Ni/Au and is evaporated at the bottom of the VCSEL. The P-type metal 241 can be Ti/Pt/Au. The substrate 210 can be an N-type heavily doped GaAs or InP substrate.

The AR-coating film 250 lowers the overall reflectivity of the top portion so that it is difficult for the active region under the AR-coating film to reach the threshold condition and emit laser beam. Thus, the threshold current density of the active region of those area increases. On the other hand, the current flows through the central active region under the P-type DBR without AR-coating reaches threshold current at lower current level and emits single mode-laser beam. One obtains a single-mode laser beam output from the light-emitting window 252 with a diameter smaller than 5 μm at the center. Moreover, the AR-coating film 250 can be made of materials with high refractive indices, such as Ge (with a refractive index of 5.2+0.65j) or single-layer or multiple-layer AR's made of other dielectrics.

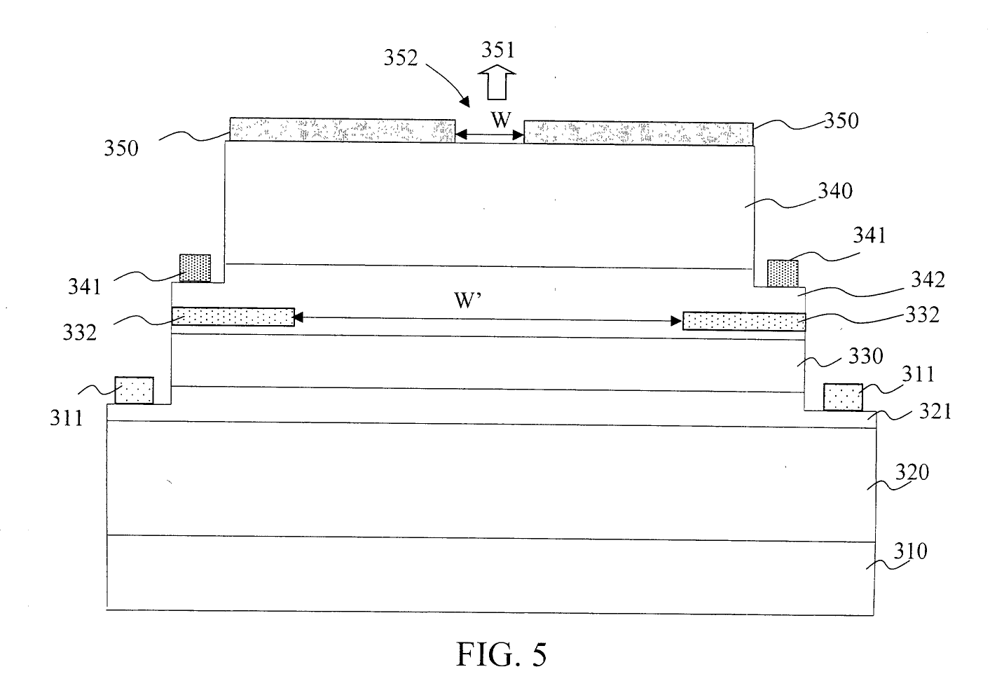

Finally, in FIG. 5 the VCSEL structure can be used in the long-wavelength or visible light regions. In this structure, the DBR has a larger thickness and a higher series resistance. It is difficult to make by using the conventional proton implantation technology. Thus, it is made using the oxide confinement technology and the structure with intracavity contracts.

In the drawing, the device consists of, from bottom to top, a substrate 310, a bottom DBR 320, an N-type contact layer 321, an N-type metal 311, an active region 330, a P-type contact layer 342, a top DBR 340, an oxide layer 332, a P-type metal 341, and an AR-coating film 350. The AR-coating film 350 is the essence of the invention.

The bottom laser mirror of the VCSEL device is the bottom DBR 320. The top laser mirror is the top DBR 340. At the center of the AR-coating film 350, a light-emitting window 352 is formed with a diameter W smaller than 5 μm. The laser beam 351 (single-mode) is output from the top light-emitting window 352. Besides, the bottom and top DBR's 320, 340 are made of tens of pairs of materials with high-low refractive indices. The thickness is ¼ of the wavelength λ of the emitted light, so that the total reflectivity reaches above 98%. The active region 330 is comprised of a quantum well and confinement layers. The active region 330 has a thickness of the emitted light wavelength λ. Its thickness can also be designed to the multiples of λ/2. The oxide layer 332 is formed by using the selective oxidation technology. The unoxidized region has a diameter W′. It has high impedance so that the electrical current flows to the central light-emitting active region. The N-type metal 311 can be AuGe/Ni/Au and is formed on top of the heavily doped N-type contact layer 321. The P-type metal 341 can be Ti/Pt/Au and is formed on top of the heavily doped P-type contact layer 342. The substrate 310 can be an N-type heavily doped, or semi-insulating GaAs or InP substrate.

The AR-coating film 350 lowers the overall reflectivity of the top portion so that it is more difficult for the active region under the AR-coating film to reach the threshold condition and emit laser beams. Thus, the threshold current density of the region increases. On the other hand, the current flows the central active region under the P-type DBR without AR-coating reaches its threshold current at lower current level and emits single-more laser beam. emitting the single-mode laser light. One obtains a single-mode laser beam output from the light-emitting window 352 with a diameter smaller than 5 μm at the center. Moreover, the AR-coating film 350 can be made of materials with high refractive indices, such as Ge (with a refractive index of 5.2+0.65j) or single-layer or multiple-layer AR's made of other dielectrics.

In summary, the invention provides a method for forming a VCSEL device with single-mode output, which utilizes the conventional manufacturing method for forming a VCSEL device with multiple transverse mode output. The steps of the method includes: using the typical multiple transverse mode VCSEL device to finish a VCSEL device, and forming an AR-coating film on top of the original VCSEL light-emitting window, wherein a light-emitting window is formed at the center of the AR-coating film. The diameter of the light-emitting window is preferably to be 5 μm or smaller.

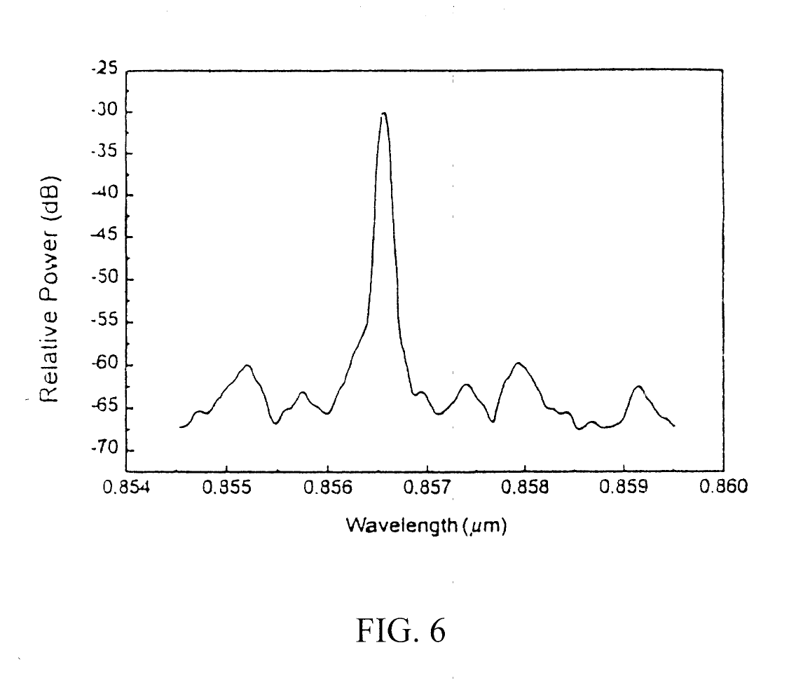

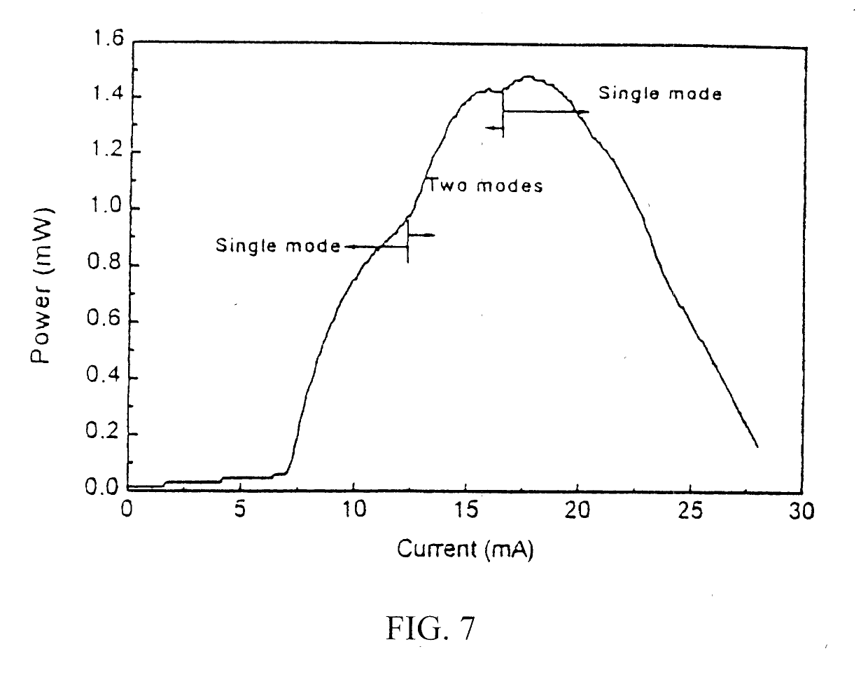

After experiments, the single-mode output spectrum from a Ge AR-coating film is shown in FIG. 6. One notices that when the current is below 11 mA, the invention can achieve a stable single-mode laser output. The power-current character is shown in FIG. 7. Under different current levels, the invention can obtain different mode states. One also obtains the single-mode output with a higher current level.

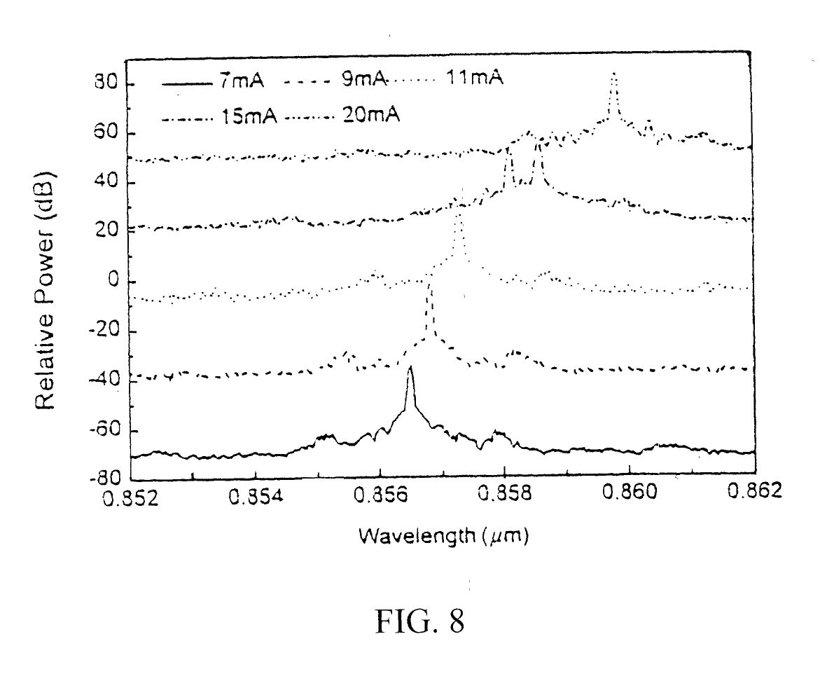

From the output spectra diagram in FIG. 8, it is easy to see that by controlling the current we can control the output of single-mode laser. Therefore, the invention can provide a method of controlling the single-mode laser output using the disclosed single-mode VCSEL.

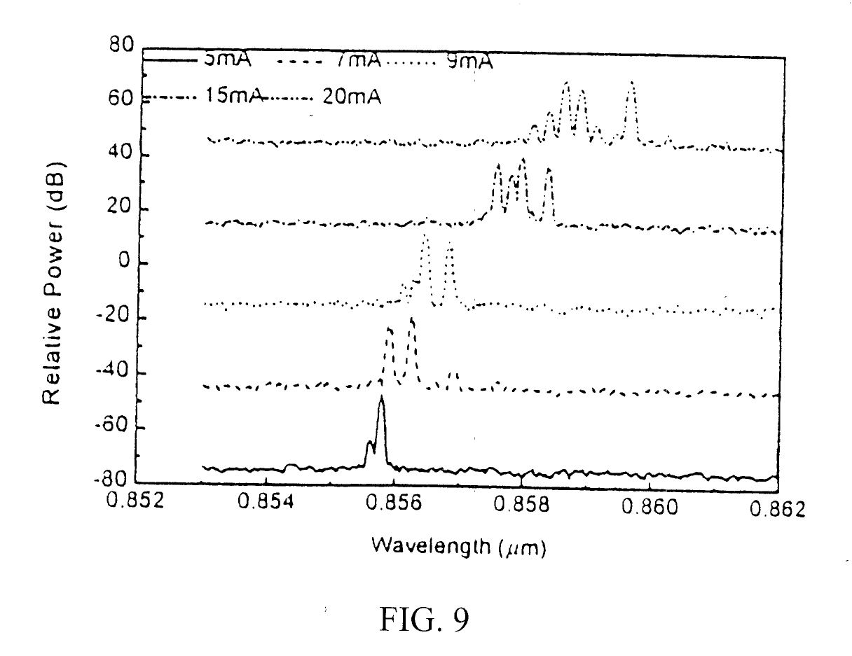

FIG. 9 shows the spectrum of a VCSEL with a light-emitting aperture of 20 μm without the AR-coating film. As the current increases, the number of modes also increases. Unlike the invention, a stable single-mode output cannot be obtained.

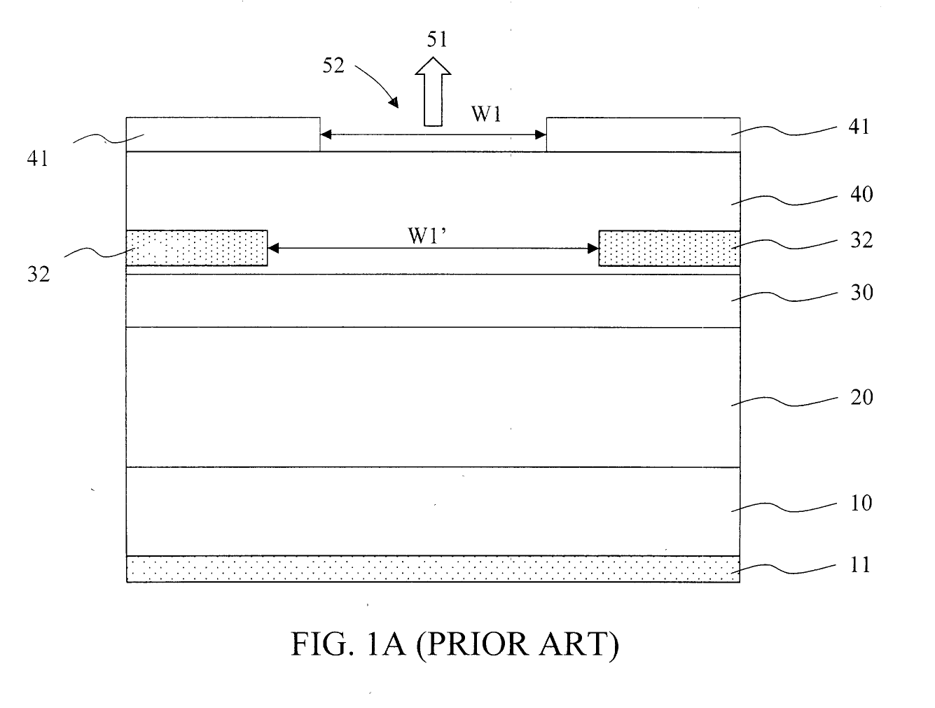

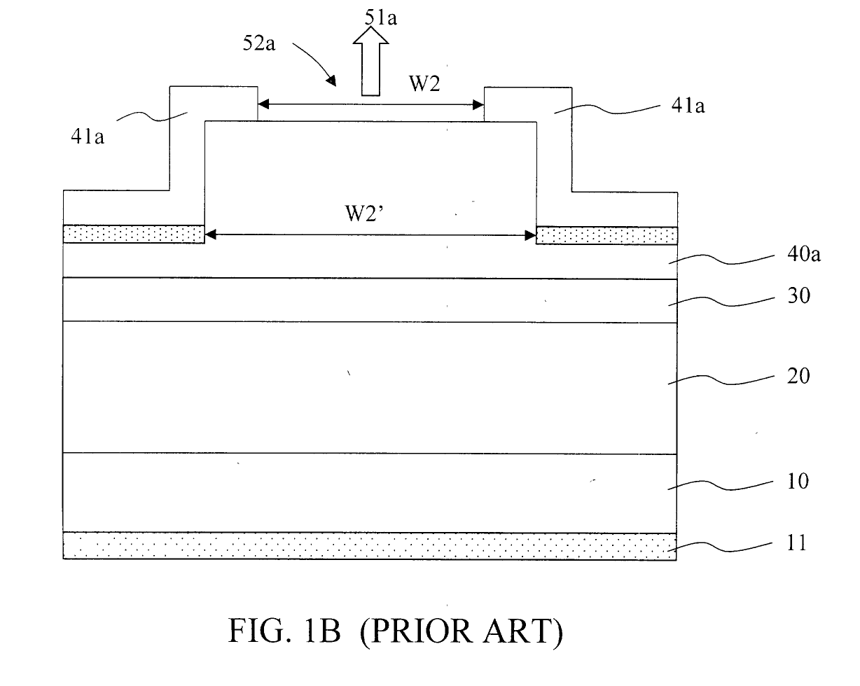

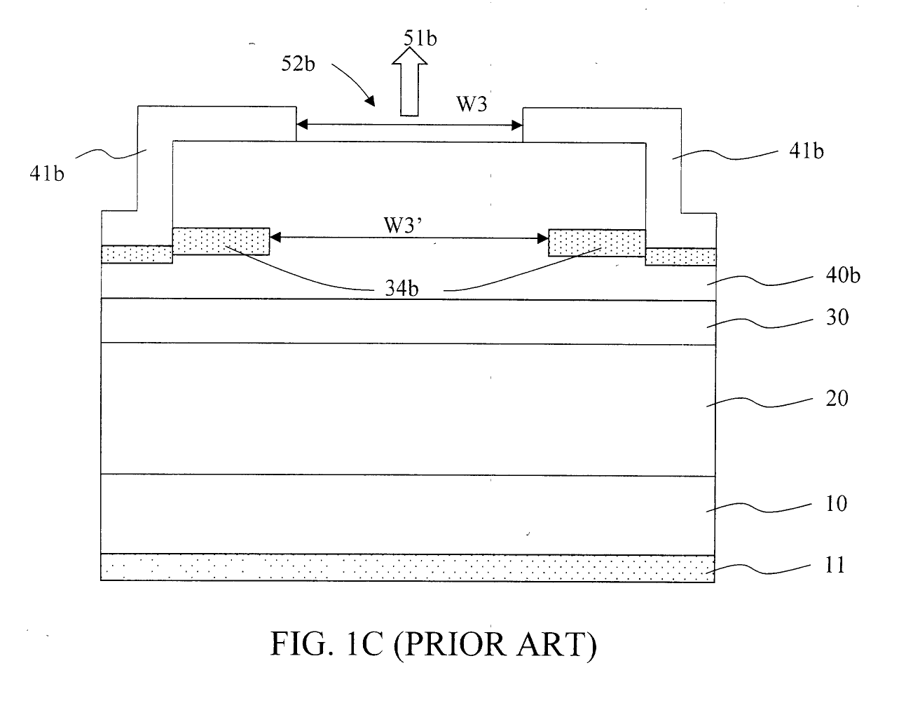

Using the disclosed single-mode VCSEL device, it is possible to obtain a low-cost single-mode output laser source using a simple manufacturing process. In this method, there is no need to decrease the diameter of the un-implanted region or the un-oxidized layer of the VCSEL, such as W1′ and W3′ in FIG. 1, and W′ in FIG. 3, FIG. 4 and FIG. 5.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A single-mode vertical cavity surface emitting laser (VCSEL) diode, which comprises:
a multiple transverse mode VCSEL with a top light-emitting area; and
an antireflection-coating (AR-coating) film, which is coated in the top light-emitting area of the multiple transverse mode VCSEL and is formed with a light-emitting window for restricting the output of the multiple transverse mode VCSEL device as a single-mode laser beam.

2. The single-mode VCSEL diode of claim 1, wherein the multiple transverse mode VCSEL device is a proton-implanted VCSEL comprising:
a substrate;
an N-type metal formed on the lower surface of the substrate;
an N-type distributed Bragg reflector (DBR) formed on top of the substrate;
an active region, which is formed on the N-type DBR for an electrical current to flow through to generate the single-mode laser beam;
a P-type DBR formed on top of the active region;
a proton-implanted region, which is formed in the P-type DBR and has a high series resistance for confining the flowing direction of the current so that the current flows toward the un-implanted region at the center of the active region; and
a P-type metal, which is formed on top of the P-type DBR to form the top light-emitting region and P-type metal contacts for restricting the laser beam to output from the top light-emitting area.

3. The single-mode VCSEL diode of claim 2, wherein the substrate is selected from the group consisting of a heavily doped N-type GaAs and InP.

4. The single-mode VCSEL diode of claim 2, wherein the N-type and P-type DBR's are made of compound semiconductor materials.

5. The single-mode VCSEL diode of claim 2, wherein the N-type metal is selected from the group consisting of AuGe, Ni, and Au.

6. The single-mode VCSEL diode of claim 2, wherein the P-type metal is selected from the group consisting of Ti, Pt and Au.

7. The single-mode VCSEL diode of claim 1, wherein the multiple transverse mode VCSEL device is an oxide-confined VCSEL device comprising:
a substrate;
an N-type metal formed on the lower surface of the substrate;
an N-type distributed Bragg reflector (DBR) formed on top of the substrate;
an active region, which is formed on top of the N-type DBR for an electrical current to flow through to generate the single-mode laser beam;
a P-type DBR formed on top of the active region;
an oxide layer, which is formed within the P-type DBR and has a high resistance for confining the flowing direction of the current so that the current flows toward the un-oxidized region at the center of the active region; and
a P-type metal, which is formed on the P-type DBR to form the top light-emitting area for restricting the laser beam to output from the top light-emitting area.

8. The single-mode VCSEL diode of claim 7, wherein the substrate is selected from the group consisting of a heavily doped N-type GaAs and InP.

9. The single-mode VCSEL diode of claim 7, wherein the N-type and P-type DBR's are made of compound semiconductor materials.

10. The single-mode VCSEL diode of claim 7, wherein the N-type metal is selected from the group consisting of AuGe, Ni, and Au.

11. The single-mode VCSEL diode of claim 7, wherein the P-type metal is selected from the group consisting of Ti, Pt anid Au.

12. The single-mode VCSEL diode of claim 1, wherein the multiple transverse mode VCSEL device is an oxide-confined VCSEL with intracavity contacts comprising:
a substrate;
a bottom distributed Bragg reflector (DBR) formed on top of the substrate;
a heavily-doped N-type contact layer formed on top of the bottom DBR;
an N-type metal formed on top of the heavily-doped N-type contact layer;
an active region, which is formed on top of the bottom DBR for an current to flow through, generating the laser beam;
an heavily-doped P-type contact layer formed on top of the active region;
a oxide layer, which is formed in the P-type DBR and has a high resistance for restricting the flowing direction of the current so that the current flows toward the un-oxidized at the center of the active region;
a top DBR formed on top of the P-type contact layer; and
a P-type metal, which is formed on the P-type contact layer.

13. The single-mode VCSEL diode of claim 12, wherein the substrate is selected from the group consisting of a heavily doped N-type GaAs and InP.

14. The single-mode VCSEL diode of claim 12, wherein the N-type and P-type DBR's are made of compound semiconductor materials.

15. The single-mode VCSEL diode of claim 12, wherein the N-type metal is selected from the group consisting of AuGe, Ni, and Au.

16. The single-mode VCSEL diode of claim 12, wherein the P-type metal is selected from the group consisting of Ti, Pt and Au.

17. The single-mode VCSEL diode of claim 1, wherein the top light-emitting area has a diameter greater than 5 μm.

18. The single-mode VCSEL diode of claim 1, wherein the light-emitting window is formed by partially lifting the AR-coating film off after the AR-coating film is formed.

19. The single-mode VCSEL diode of claim 1, wherein the light-emitting window is formed by partially etching the AR-coating film off after the AR-coating film is formed.

20. The single-mode VCSEL diode of claim 1, wherein the light-emitting window has a diameter smaller than or equal to 5 μm.

21. The single-mode VCSEL diode of claim 1, wherein the AR-coating film is made of a high refractive index material.

22. The single-mode VCSEL diode of claim 1, wherein the AR-coating film is selected from the group consisting of Ge (with a refractive index of 5.2+0.65j) and other dielectrics.

23. The single-mode VCSEL diode of claim 1, wherein the AR-coating film is selected from the group consisting of single-layer and multiple-layer dielectric AR-coating films.

24. A method for forming a single-mode VCSEL diode, which employs a manufacturing procedure for forming a multiple transverse mode VCSEL to form the single-mode VCSEL, the method comprising the steps of:
providing a manufacturing procedure for making a multiple transverse mode VCSEL to finish a VCSEL; and
forming an AR-coating film with a light-emitting window on top of the VCSEL.

25. The method of claim 24, wherein the light-emitting window has a diameter smaller than or equal to 5 μm.

26. The method of claim 24, wherein the AR-coating film is made of a high refractive index material.

27. The method of claim 24, wherein the AR-coating film is selected from the group consisting of Ge (with a refractive index of 5.2+0.65j) and other dielectrics.

28. The single-mode VCSEL diode of claim 1, wherein the AR-coating film is selected from the group consisting of single-layer and multiple-layer dielectric AR-coating films.
